(19) United States
(12) Patent Application Publication
(10) Pub. No.: US 2024/0251641 A1
(43) Pub. Date: Jul. 25, 2024

(54) DISPLAY PANEL, DISPLAY DEVICE, AND METHOD FOR PREPARING THE SAME

(71) Applicant: Visionox Technology Inc., Suzhou, Jiangsu (CN)

(72) Inventors: Haohan ZHANG, Suzhou (CN); Yiming XIAO, Suzhou (CN); Yuan YAO, Suzhou (CN); Bowen YANG, Suzhou (CN); Xuejing ZHU, Suzhou (CN); Liusong NI, Suzhou (CN)

(73) Assignee: Visionox Technology Inc., Suzhou, Jiangsu (CN)

(21) Appl. No.: 18/625,621

(22) Filed: Apr. 3, 2024

Related U.S. Application Data
(63) Continuation of application No. PCT/CN2023/110841, filed on Aug. 2, 2023.

(30) Foreign Application Priority Data
Aug. 2, 2022 (CN) 202210923525.7
Aug. 1, 2023 (CN) 202310955134.8

(51) Int. Cl. H10K 59/80; H10K 59/12; H10K 59/122

(52) U.S. Cl. CPC H10K 59/873; H10K 59/1201; H10K 59/122; H10K 59/879

(57) ABSTRACT

A display panel, a display device, and a method for preparing the same. The display panel includes a substrate, a spacer layer disposed on the substrate, a light-emitting layer, and an encapsulation layer located on a side of the light-emitting layer away from the substrate. A second portion is located on a side of a first portion facing the substrate. An orthographic projection area of the first portion on the substrate is greater than that of the second portion on the substrate. The second portion is sunken relative to the first portion to form a groove. A first encapsulation portion is deposited in an isolation space. At least a portion of the first encapsulation portion is located in the groove. A second encapsulation portion is prepared on a side of the first encapsulation portion away from the substrate.

### CROSS-REFERENCE TO RELATED APPLICATIONS

The present disclosure is a continuation of International Application No. PCT/CN2023/110841, filed on Aug. 2, 2023, which claims priority to Chinese Patent Application No. 202210923525.7 entitled “DISPLAY PANEL, DISPLAY DEVICE, AND METHOD FOR PREPARING THE SAME” filed on Aug. 2, 2022 and Chinese Patent Application No. 202310955134.8 entitled “DISPLAY PANEL, DISPLAY DEVICE, AND METHOD FOR PREPARING THE SAME” filed on Aug. 1, 2023, all of which are incorporated herein by reference in their entireties.

### TECHNICAL FIELD

The present disclosure relates to the field of display, and specifically to a display panel, a display device, and a method for preparing the same.

### BACKGROUND

With the rapid development of electronic devices, users have increasingly high requirements for display effects, so that the screen display of electronic devices has received increasing attention from the industry.

In order to improve the display effect of screens of electronic devices, the thin film encapsulation process is a key factor in ensuring the display effect in display panels, and the encapsulation effect directly affects service lives of the display panels. Therefore, the stability of thin film encapsulation is crucial. In existing technologies, an encapsulation layer forms holes due to its excessive thickness, resulting in poor encapsulation performance.

### SUMMARY

Embodiments of the present disclosure provide a display panel, a display device, and a method for preparing the same to improve the problem of poor encapsulation performance.

Embodiments in a first aspect of the present disclosure provide a display panel, including: a substrate; a pixel definition layer located on the substrate, where the pixel definition layer includes isolation portions and pixel openings enclosed by the isolation portions, and at least part of each pixel electrode is exposed from a respective pixel opening; a spacer layer located on the substrate including a first portion and a second portion located on a side, facing the substrate, of the first portion, an orthographic projection area of the first portion on the substrate being greater than that of the second portion on the substrate, the spacer layer enclosing an isolation space, and the spacer layer having a groove protruding to a side wall of the isolation space; a light-emitting layer including a light-emitting unit located in the isolation space; and an encapsulation layer located on a side, away from the substrate, of the light-emitting layer, where the encapsulation layer includes a first encapsulation portion and a second encapsulation portion that are laminated, at least a portion of the first encapsulation portion is located in the groove, and the second encapsulation portion is located on a side, away from the substrate, of the first encapsulation portion.

According to embodiments in the first aspect of the present disclosure, the display panel further includes a pixel definition layer located on the substrate, where the pixel definition layer includes a plurality of pixel defining portions and a plurality of pixel openings enclosed by the pixel defining portions, and at least part of each pixel electrode is exposed from a respective pixel opening. According to any of the foregoing implementations in the first aspect of the present disclosure, a first electrode layer located on a side, away from the substrate, of the light-emitting unit is further included, where the first electrode layer includes a body portion, and the body portion is connected to the second portion.

According to any of the foregoing embodiments in the first aspect of the present disclosure, the first encapsulation portion is located on a side, away from the light-emitting unit, of the body portion, and the first encapsulation portion is located on the side, facing the substrate, of the first portion.

According to any of the foregoing embodiments in the first aspect of the present disclosure, the first encapsulation portion includes a second covering portion covering a side surface of the second portion.

According to any of the foregoing embodiments in the first aspect of the present disclosure, the first encapsulation portion further includes a first covering portion, the first covering portion covers a surface, away from the light-emitting unit, of the body portion, and the second covering portion is connected to a periphery of the first covering portion.

According to any of the foregoing embodiments in the first aspect of the present disclosure, the first encapsulation portion further includes a third covering portion connected to a periphery of the second covering portion and covering the surface, facing the substrate, of the first portion.

According to any of the foregoing embodiments in the first aspect of the present disclosure, the display panel further includes a filter unit, the filter unit is located between the body portion of the first electrode layer and the first encapsulation portion, a refractive index of the filter unit is n0, a refractive index of the first encapsulation portion is n1, and a refractive index of the second encapsulation portion is n2, satisfying the following relationship:

$${n}_{1} = \sqrt{{n}_{0} *} {n}_{2} .$$

According to any of the foregoing embodiments in the first aspect of the present disclosure, the second encapsulation portion is at least partially disposed within the isolation space.

According to any of the foregoing embodiments in the first aspect of the present disclosure, the second encapsulation portion includes a first portion and a second portion that are integrated, the first portion is located within the isolation space, and the second portion is located on a surface, away from the substrate, of the spacer layer.

According to any of the foregoing embodiments in the first aspect of the present disclosure, a thickness of the first encapsulation portion is smaller than that of the second encapsulation portion.

According to any of the foregoing embodiments in the first aspect of the present disclosure, the thickness of the first encapsulation portion ranges from 0.1 μm to 0.5 μm.

According to any of the foregoing embodiments in the first aspect of the present disclosure, the encapsulation layer further includes a third organic encapsulation portion, the third organic encapsulation portion is located on a side, away from the substrate, of the second encapsulation portion, the display panel further includes a display area and a non-display area disposed around the display area, the non-display area includes a blocking portion, the blocking portion is disposed around the display area, and the third organic encapsulation portion is located within an area enclosed by the blocking portion.

Embodiments in a second aspect of the present disclosure provide a display device, including the display panel in any of the foregoing embodiments.

Embodiments in a third aspect of the present disclosure provide a method for preparing a display panel, including:
preparing a spacer layer on a substrate, where the spacer layer includes a first portion and a second portion located on a side, facing the substrate, of the first portion, an orthographic projection area of the first portion on the substrate is greater than that of the second portion on the substrate, the spacer layer encloses an isolation space, and the spacer layer having a groove protruding to a side wall of the isolation space; and
preparing a light-emitting layer and an encapsulation layer on the substrate, where the light-emitting layer includes a light-emitting unit located in the isolation space, the encapsulation layer includes a first encapsulation portion and a second encapsulation portion that are laminated, the first encapsulation portion is located in the isolation space, and the second encapsulation portion is located on a side, away from the substrate, of the first encapsulation portion.

According to any of the foregoing embodiments in the third aspect of the present disclosure, the method further includes:
preparing a pixel definition layer on the substrate, where the pixel definition layer includes pixel defining portions and pixel openings enclosed by the pixel defining portions, and at least part of each pixel electrode is exposed from a respective pixel opening; the pixel openings include first pixel openings, second pixel openings, and third pixel openings; the light-emitting units include first light-emitting units located within the first pixel openings, the second light-emitting units located within the second pixel openings, and the third light-emitting units located within the third pixel openings; the first encapsulation portion includes a first encapsulation portion located on a side, away from the substrate, of the first light-emitting unit, a second encapsulation portion located on a side, away from the substrate, of the second light-emitting unit, and a third encapsulation portion located on a side, away from the substrate, of the third light-emitting unit, and
in the step of preparing a light-emitting layer and an encapsulation layer on the substrate:
disposing a first light-emitting material layer and a first encapsulation sub material layer on a side, away from the substrate, of the pixel definition layer, and patterning the first light-emitting material layer and the first encapsulation sub material layer to form a first light-emitting unit and a first encapsulation portion;
continuing to dispose a second light-emitting material layer and a second encapsulation sub material layer on the side, away from the substrate, of the pixel definition layer, and patterning the second light-emitting material layer and the second encapsulation sub material layer to form a second light-emitting unit and a second encapsulation portion;
continuing to dispose a third light-emitting material layer and a third encapsulation sub material layer on the side, away from the substrate, of the pixel definition layer, and patterning the third light-emitting material layer and the third encapsulation sub material layer to form a third light-emitting unit and a third encapsulation portion; and
preparing a second encapsulation portion on the first encapsulation portion, the second encapsulation portion, the third encapsulation portion, and the pixel definition layer.

According to the display panel in the embodiments of the present disclosure, the display panel includes a substrate, a spacer layer disposed on the substrate, a light-emitting layer, and an encapsulation layer located on a side, away from the substrate, of the light-emitting layer. The second portion is located on a side, facing the substrate, of the first portion, and the orthographic projection area of the first portion on the substrate is greater than that of the second portion on the substrate, so that at least a portion of the first portion is suspended, namely, the second portion is sunken relative to the first portion to form a groove. When the first encapsulation portion is prepared, the first encapsulation portion is separated by the spacer layer and deposited in the isolation space, and at least a portion of the first encapsulation portion is located in the groove to cover a side, facing the isolation space, of the second portion. Then, the second encapsulation portion is prepared on the side, away from the substrate, of the first encapsulation portion, and the second encapsulation portion is prepared on the whole side to achieve good cladding performance and further improve the overall encapsulation performance of the encapsulation layer. The first encapsulation portion and the second encapsulation portion are prepared in steps, where the first encapsulation portion can well clad the second portion, which can improve the problem of degradation of the encapsulation performance of the encapsulation layer due to holes easily formed between the encapsulation layer and the spacer layer when a first encapsulation layer and a second encapsulation layer are simultaneously prepared with a large thickness.

### DESCRIPTION OF THE DRAWINGS

Other features, objectives, and advantages of the present invention will become more apparent by reading the following detailed descriptions of non-restrictive embodiments with reference to the accompanying drawings, where the same or similar reference numerals indicate the same or similar features, and the accompanying drawings are not drawn to actual scale.

FIG. 1 is a top schematic diagram of a display panel provided in an embodiment of the present disclosure;

FIG. 2 is a cross-sectional view taken along line B-B in FIG. 1;

FIG. 3 is a partially enlarged view of FIG. 2;

FIG. 4 is a schematic flowchart of a method for preparing a display panel provided in an embodiment of the present disclosure;

FIG. 5 is a schematic flowchart of steps in a method for preparing a display panel provided in an embodiment of the present disclosure; and

FIGS. 6 to 15 are schematic diagrams of preparing processes of a method for preparing a display panel provided in an embodiment of the present disclosure.

Reference numerals are described as follows:
10. Display panel;
100. Substrate;
200. Pixel definition layer; 210. Pixel defining portion; 220. Pixel opening; 221. First pixel opening; 222. Second pixel opening; 223. Third pixel opening;
300. Spacer layer; 310. First portion; 320. Second portion; 330. Isolation space; 340. Groove;
400. Light-emitting layer; 410. Light-emitting unit; 411. First light-emitting unit; 412. Second light-emitting unit; 413. Third light-emitting unit;
500. Encapsulation layer; 501. First encapsulation portion; 502. Second encapsulation portion; 503. Third encapsulation portion; 510. First encapsulation portion; 511. First covering portion; 512. Second covering portion; 513. Third covering portion; 520. Second encapsulation portion; 521. First portion; 522, Second portion; 530. Third organic encapsulation portion; 540; Fourth inorganic encapsulation portion;
600. First electrode layer; 610. Body portion;
700. Flattened layer; 710. Blocking portion;
800. Pixel electrode;
900. Filter unit;
AA. Display area; NA. Non-display area.

### DETAILED DESCRIPTION

Features and exemplary embodiments of various aspects of the present disclosure will be described in detail below. The following descriptions of the embodiments are merely to provide a better understanding of the present invention by showing examples of the present invention.

It should be noted that the relational terms herein, such as first and second, are merely used for distinguishing one entity or operation from another, and do not necessarily require or imply that any actual relationship or sequence exists between these entities or operations. Moreover, the terms “include”, “comprise”, and any variants thereof are intended to cover a non-exclusive inclusion.

It should be understood that when the structure of a component is described and when one layer or area is referred to as located “on” or “above” another layer or area, the one layer or area may be directly located on the another layer or area, or other layers or areas may be included between the one layer or area and the another layer or area. In addition, if the component is flipped, the one layer or area will be located “below” or “under” the another layer or area.

On an electronic device such as a mobile phone or a tablet computer, a photosensitive component such as a front camera, an infrared light sensor, or a proximity sensor needs to be integrate on a side where a display panel is disposed. In some embodiments, a transparent display area may be disposed on the foregoing electronic device, and the photosensitive component may be disposed on the back of the transparent display area. In order to improve the photosensitive performance of the photosensitive component, its light transmittance needs to be increased.

In order to improve the display effect of screens of electronic devices, the thin film encapsulation process is a key factor in ensuring the display effect in display panels, and the encapsulation effect directly affects service lives of the display panels. Therefore, the stability of thin film encapsulation is crucial. In existing technologies, after a light-emitting unit is prepared, a full-thickness encapsulation layer is directly deposited. When a film is formed around a spacer layer, holes are formed on side walls of the spacer layer. After the encapsulation layer is etched, the holes still exist, resulting in poor encapsulation performance.

To solve the above problems, the embodiments of the present disclosure provide a display panel, a display device, and a preparing method for a display panel. Each embodiment of the display panel, the display device, and the preparing method for the display panel will be explained below with reference to the accompanying drawings.

An embodiment of the present disclosure provides a display panel. The display panel may be an organic light-emitting diode (OLED) display panel.

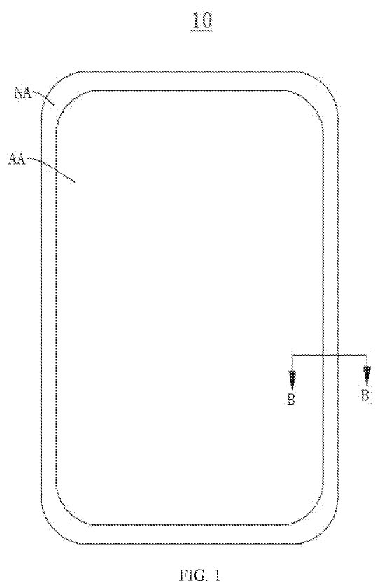

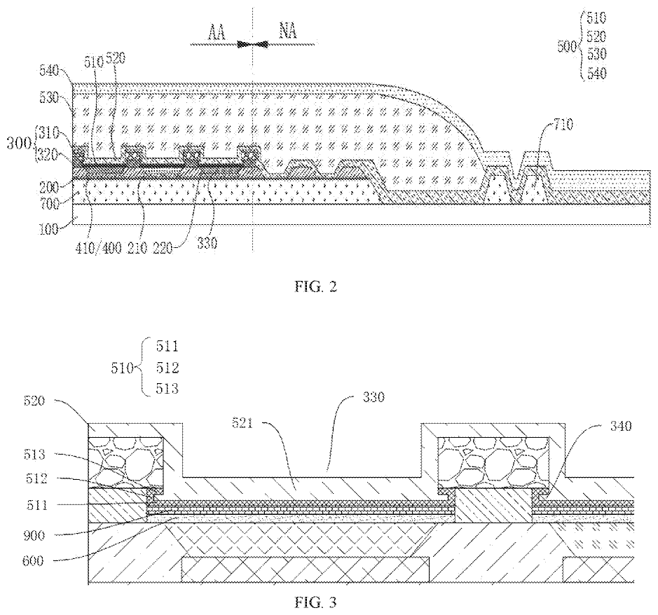

Refer to FIGS. 1 to 3 together, where FIG. 1 is a top schematic diagram of a display panel provided in an embodiment of the present disclosure; FIG. 2 is a cross-sectional view taken along line B-B in FIG. 1; and FIG. 3 is a partially enlarged view of FIG. 2.

As shown in FIGS. 1 to 3, an embodiment in a first aspect of the present disclosure provides a display panel 10. The display panel 10 includes: a substrate 100; a spacer layer 300 located on the substrate 100, where the spacer layer 300 includes a first portion 310 and a second portion 320 located on a side, facing an isolation space 330, of the first portion 310, an orthographic projection area of the first portion 310 on the substrate 100 is greater than that of the second portion 320 on the substrate 100, the spacer layer 300 encloses the isolation space 330, and the spacer layer 300 has a groove 340 protruding to a side wall of the isolation space 330; a light-emitting layer 400 including a light-emitting unit 410 located in the isolation space 330; and an encapsulation layer 500 located on a side, away from the substrate 100, of the light-emitting layer 400, where the encapsulation layer 500 includes a first encapsulation portion 510 and a second encapsulation portion 520 that are laminated, at least a portion of the first encapsulation portion 510 is located in the groove 340, and the second encapsulation portion 520 is located on a side, away from the substrate 100, of the first encapsulation portion 510.

According to the display panel 10 in the embodiment of the present disclosure, the display panel 10 includes a substrate 100, a spacer layer 300 disposed on the substrate 100, a light-emitting layer 400, and the encapsulation layer 500 located on a side, away from the substrate 100, of the light-emitting layer 400. The second portion 320 is located on a side, facing the substrate 100, of the first portion 310, and the orthographic projection area of the first portion 310 on the substrate 100 is greater than that of the second portion 320 on the substrate 100, so that at least a portion of the first portion 310 is suspended, namely, the second portion 320 is sunken relative to the first portion 310 to form a groove 340. When the first encapsulation portion 510 is prepared, the first encapsulation portion 510 is separated by the spacer layer 300 and deposited in the isolation space 330, and at least a portion of the first encapsulation portion 510 is located in the groove 340 to cover a side, facing the isolation space 330, of the second portion 320. Then, the second encapsulation portion 520 is prepared on the side, away from the substrate 100, of the first encapsulation portion 510, and the second encapsulation portion 520 is prepared on the whole side to achieve good cladding performance and further improve the overall encapsulation performance of the encapsulation layer 500. The first encapsulation portion 510 and the second encapsulation portion 520 are prepared in steps, where the first encapsulation portion 510 can well clad the second portion 320, which can improve the problem of degradation of the encapsulation performance of the encapsulation layer 500 due to holes easily formed between the encapsulation layer 500 and the spacer layer 300 when the thick encapsulation layer is made of the same material at a time.

Optionally, the spacer layer 300 includes an isolation structure for isolating the light-emitting layer 400 to form mutually spaced light-emitting units 410 when the light-emitting layer 400 is prepared.

Optionally, the display panel 10 includes a pixel definition layer 200, the pixel definition layer 200 is located on the substrate 100, the pixel definition layer 200 includes pixel defining portions 210 and pixel openings 220 enclosed by the pixel defining portions 210, at least part of each pixel electrode 800 is exposed from a respective pixel opening 220, the pixel opening 220 is used for disposing the light-emitting unit 410 to achieve light emission of the display panel 10, and the pixel defining portion 210 is used for defining a light-emitting area of the display panel 10. In some optional embodiments, a thickness of the first encapsulation portion 510 is smaller than that of the second encapsulation portion 520.

In these optional embodiments, the first encapsulation portion 510 is thinner, so that the first encapsulation portion 510 obtains better diffraction, and the first encapsulation portion 510 fits more tightly with the spacer layer 300 in the groove 340 when the first encapsulation portion 510 is prepared, to reduce the possibility of hole formation. The second encapsulation portion 520 is thicker and has good cladding performance, which can improve the overall encapsulation performance of the encapsulation layer 500. Optionally, a material of the first encapsulation portion 510 includes silicon oxide or silicon oxynitride, which can improve the optical performance of the display panel 10.

Optionally, a material of the second encapsulation portion 520 includes silicon nitride, which has good cladding performance to improve the encapsulation performance.

Optionally, the display panel 10 further includes a pixel definition layer 200, the pixel definition layer 200 is located on the substrate 100, the pixel definition layer 200 includes pixel defining portions 210 and pixel openings 220 enclosed by the pixel defining portions 210, at least part of each pixel electrode 800 is exposed from a respective pixel opening 220, the pixel defining portion 210 is used for defining a light-emitting area of the display panel 10, and the pixel opening 220 is used for disposing the light-emitting unit 410 to achieve light-emitting display of the display panel 10.

Optionally, a distance between a surface, facing the substrate 100, of the first portion 310 and the substrate 100 is a first distance, a distance between a surface, away from the substrate 100, of the first encapsulation portion 510 and the substrate 100 is a second distance, and the second distance is smaller than or equal to the first distance, that is, the first encapsulation portion 510 is completely located on the side, facing the substrate 100, of the first portion 310, thereby improving the fit reliability between the first encapsulation portion 510 and the second portion 320 and reducing the formation of holes.

With reference to FIG. 3, in some optional embodiments, the display panel 10 further includes a first electrode layer 600 located on a side, away from the substrate 100, of the light-emitting unit 410, the first electrode layer 600 includes a body portion 610, and the body portion 610 is connected to the second portion 320.

Optionally, a material for the second portion 320 includes a metal material.

In these optional embodiments, the body portions 610 on two adjacent light-emitting units 410 may be connected to each other through the second portion 320, that is, the body portions 610 on two adjacent light-emitting units 410 may be electrically connected as a surface electrode through the spacer layer 300.

In some optional embodiments, the first encapsulation portion 510 is located on a side, away from the light-emitting unit 410, of the body portion 610, and the first encapsulation portion 510 is located on the side, facing the substrate 100, of the first portion 310.

In these optional embodiments, the first encapsulation portion 510 is located on the side, facing the substrate 100, of the first portion 310 to prevent water vapor from entering the light-emitting unit 410, thereby further improving the encapsulation effect and improving the risk of intrusion of water vapor into the light-emitting unit 410.

As shown in FIG. 3, in some optional embodiments, the first encapsulation portion 510 includes a second covering portion 512, and the second covering portion 512 covers a side surface of the second portion 320. Specifically, the first encapsulation portion 510 may further include a first covering portion 511, where the first covering portion 511 covers a surface, away from the light-emitting unit 410, of the body portion 610; and a second covering portion 512 connected to a periphery of the first covering portion 511.

In these optional embodiments, the first covering portion 511 is used for encapsulating the body portion 610 and the light-emitting unit 410, and the second covering portion 512 covers the side surface of the second portion 320, so that when the second encapsulation portion 520 is prepared, the second encapsulation portion 520 covers the side, away from the substrate 100, of the first encapsulation portion 510, to avoid degradation of the encapsulation performance caused by the formation of holes in the encapsulation layer 500 on the side of the second portion 320 due to the excessive depth of the groove.

Optionally, the first encapsulation portion 510 further includes a third covering portion 513 connected to a periphery of the second covering portion 512 and covering the surface, facing the substrate 100, of the first portion 310. When the second encapsulation portion 520 is deposited, it is deposited downwards along the side surface of the first portion 310 and the third covering portion 513, thereby reducing the possibility of hole formation and improving the encapsulation performance.

In some optional embodiments, the display panel 10 further includes a filter unit, the filter unit 900 is located between the body portion 610 of the first electrode layer 600 and the first encapsulation portion 510, a refractive index of the filter unit 900 is no, a refractive index of the first encapsulation portion 510 is n1, and a refractive index of the second encapsulation portion 520 is n2, satisfying the following relationship:

$${n}_{1} = \sqrt{{n}_{0} *} {n}_{2} .$$

In these optional embodiments, when the refractive index n0 of the filter unit 900, the refractive index n1 of the first encapsulation portion 510, and the refractive index n2 of the second encapsulation portion 520 satisfy the above relationship, the light-emitting efficiency of the light-emitting unit 410 is the highest.

In some optional embodiments, the second encapsulation portion 520 is at least partially located within the isolation space 330. Specifically, the second encapsulation portion 520 may be completely located within the isolation space 330, or the second encapsulation portion 520 includes a first portion 521 and a second portion 522 that are integrated, the first portion 521 is located within the isolation space 330, and the second portion 522 is located on a surface, away from the substrate 100, of the spacer layer 301.

In these optional embodiments, the first portion 521 is filled in the isolation space 330 to further improve the encapsulation effect within the isolation space 330, and the first portion 521 is deposited on the side, away from the substrate 100, of the first encapsulation portion 510 to avoid degradation of the encapsulation performance due to the formation of holes in the encapsulation layer 500 on the side of the second portion 320. The second portion 522 is located on a side, away from the substrate 100, of the first portion 310 to cover the spacer layer 300 and the first portion 310, so as to further improve the encapsulation performance of the encapsulation layer 500.

Optionally, the thickness of the first encapsulation portion 510 is smaller than that of the second encapsulation portion 520. After the first encapsulation portion 510 is deposited in the isolation space 330 and etched, the second encapsulation portion 520 is deposited on the side, away from the substrate 100, of the first encapsulation portion 510. Due to the smaller thickness of the first encapsulation portion 510, after the second encapsulation portion 520 is disposed, the encapsulation layer 500 will not form holes on the periphery of the second portion 320, so that the encapsulation performance is improved.

In some optional embodiments, the thickness of the first encapsulation portion 510 ranges from 0.1 μm to 0.5 μm.

In these optional embodiments, the thickness of the first encapsulation portion 510 is greater than or equal to 0.1 μm to avoid degradation of the encapsulation performance due to the fact that the first encapsulation portion 510 is too thin, the deposited second encapsulation portion 520 is too thick, and the second encapsulation portion 520 will produce holes on the periphery of the second portion 320 after the second encapsulation portion 520 is deposited. The thickness of the first encapsulation portion 510 is smaller than or equal to 0.5 μm to avoid degradation of the encapsulation performance due to the fact that the first encapsulation portion 510 is too thick and the first encapsulation portion 510 will produce holes on the periphery of the second portion 320 after the first encapsulation portion 510 is deposited.

With reference to FIG. 2, in some optional embodiments, the encapsulation layer 500 further includes a third organic encapsulation portion 530, the third organic encapsulation portion 530 is located on a side, away from the substrate 100, of the second encapsulation portion 520, the display panel 10 further includes a display area AA and a non-display area NA disposed around the display area AA, the non-display area NA includes a blocking portion 710, the blocking portion 710 is disposed around the display area AA, and the third organic encapsulation portion 530 is located within an area enclosed by the blocking portion 710.

In these optional embodiments, the third organic sealing portion 530 is blocked by the blocking portion, which can improve the problem of impact of water vapor from the non-display area NA to the display area AA on an organic material layer in the display area AA, and can improve the sealing performance of the display panel 10.

In some optional embodiments, the encapsulation layer 500 further includes a fourth inorganic encapsulation portion 540, and the fourth inorganic encapsulation portion 540 is located on a side, away from the substrate 100, of the third organic encapsulation portion 530.

In these optional embodiments, the fourth inorganic encapsulation portion 540 covers the third organic encapsulation portion 530 to further enhance the encapsulation performance of the encapsulation layer 500.

Optionally, the third organic encapsulation portion 530 is integrated.

Optionally, the fourth inorganic encapsulation portion 540 is integrated.

Optionally, orthographic projections of the first encapsulation portion 510 and the second encapsulation portion 520 on the substrate 100 are located within an orthographic projection of the third organic encapsulation portion 530 on the substrate 100.

Optionally, the orthographic projection of the third organic encapsulation portion 530 on the substrate 100 is located within an orthographic projection of the fourth inorganic encapsulation portion 540 on the substrate 100.

In these optional embodiments, the third organic encapsulation portion 530 is integrated, and the fourth inorganic encapsulation portion 540 is integrated. On the one hand, the encapsulation performance is better, and on the other hand, preparation of the third organic encapsulation layer 500 and the fourth inorganic encapsulation layer 500 is facilitated. The second encapsulation portion 520 fully covers the first encapsulation portion 510, the third organic encapsulation portion 530 fully covers the second encapsulation portion 520, and the fourth inorganic encapsulation portion 540 fully covers the third organic encapsulation portion 530, thereby further improving the encapsulation performance of the encapsulation layer 500.

The display panel 10 has a length direction, a width direction, and a thickness direction. The blocking portion 710 is in various shapes, for example, the blocking portion 710 may extend along the length direction in a strip shape and be located on one side of the display area AA in the width direction, or the blocking portion 710 may extend along the width direction in a strip shape and be located on one side of the display area AA in the length direction.

In other embodiments, the blocking portion 710 surrounds the display area AA in a closed ring.

In these optional embodiments, the blocking portion 710 is disposed in a ring shape, so that the organic material layer can fracture at different positions around the display area AA to better improve the problem of spread of water vapor to the display area AA and improve the sealing performance of the display panel 10.

The number of blocking portions 710 may be configured in many ways. The number of blocking portions 710 may be one.

Alternatively, the number of blocking portions 710 is two or more, and the two or more blocking portions 710 are spaced apart in a direction away from the display area AA. A plurality of blocking portions 710 can further improve the sealing effect of the display panel 10.

The substrate 100 may be configured in many ways, for example, the substrate 100 may be an array substrate, the substrate 100 includes a substrate and a driving circuit layer disposed on the substrate, the driving circuit layer may be located in the display area AA, and the blocking portion 710 may be directly formed on the substrate.

Optionally, the display panel 10 further includes a flattened layer 700, and the pixel electrode 800 is disposed between the flattening layer 700 and the pixel definition layer 200. The blocking portion 710 may be disposed in the same layer and material as the flattened layer 700 to further simplify the preparing process for the display panel 10 and improve the preparing efficiency of the display panel 10.

Optionally, in any of the above embodiments, the light-emitting units 410 include first light-emitting units 411, second light-emitting units 412, and third light-emitting units 413; and the first light-emitting units 411, the second light-emitting units 412, and the third light-emitting units 413 are red light-emitting units, green light-emitting units, and blue light-emitting units, respectively, to achieve color display of the display panel 10.

An embodiment in a second aspect of the present disclosure further provides a display device, including the display panel 10 of any of the above embodiments in the first aspect. Since the display device provided by the embodiment in the second aspect of the present disclosure includes the display panel 10 of any of the above embodiments in the first aspect, the display device provided by the embodiment in the second aspect of the present disclosure has the beneficial effects of the display panel 10 of any of the above embodiments in the first aspect, and details will not be repeated here.

The display device in the embodiment of the present disclosure includes but is not limited to devices with display functions, such as a mobile phone, a personal digital assistant (PDA), a tablet computer, an e-book, a television, an access control, an intelligent fixed-line telephone, and a console.

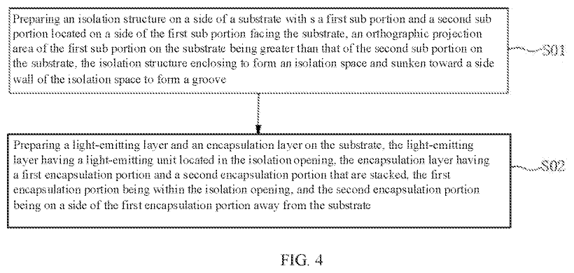

Refer to FIG. 4, and FIG. 4 is a schematic flowchart of a preparing method for a display panel provided in an embodiment of the present disclosure.

An embodiment in a third aspect of the present disclosure further provides a preparing method for a display panel 10. The display panel 10 may be the display panel 10 provided by any of the above embodiments in the first aspect. With reference to FIGS. 1 to 4 together, the preparing method includes:

Step S01: Preparing a spacer layer on a substrate, where the spacer layer includes a first portion and a second portion located on a side, facing the substrate, of the first portion, an orthographic projection area of the first portion on the substrate is greater than that of the second portion on the substrate, the spacer layer encloses an isolation space, and a side wall, facing the isolation space, of the spacer layer is sunken to form a groove.

Step S02: Preparing a light-emitting layer and an encapsulation layer on the substrate, where the light-emitting layer includes a light-emitting unit located in the isolation space, the encapsulation layer includes a first encapsulation portion and a second encapsulation portion that are laminated, the first encapsulation portion is located in the isolation space, and the second encapsulation portion is located on a side, away from the substrate, of the first encapsulation portion.

According to the preparing method provided by the embodiment in the third aspect of the present disclosure, the substrate 100 and the spacer layer 300 are prepared through step S01. The spacer layer 300 includes a first portion 310 and a second portion 320 located on a side, facing the substrate 100, of the first portion 310. The light-emitting layer 400 and the encapsulation layer 500 are prepared through step S02. The second portion 320 is located on a side, facing the substrate 100, of the first portion 310, and the orthographic projection area of the first portion 310 on the substrate 100 is greater than that of the second portion 320 on the substrate 100, so that at least a portion of the first portion 310 is suspended, namely, the second portion 320 is sunken relative to the first portion 310 to form a groove 340. When the first encapsulation portion 510 is prepared, the first encapsulation portion 510 is separated by the spacer layer 300 and deposited in the isolation space 330, and at least a portion of the first encapsulation portion 510 is located in the groove 340 to cover a side, facing the isolation space 330, of the second portion 320. Then, the second encapsulation portion 520 is prepared on the side, away from the substrate 100, of the first encapsulation portion 510, and the second encapsulation portion 520 is prepared on the whole side to achieve good cladding performance and further improve the overall encapsulation performance of the encapsulation layer 500. The first encapsulation portion 510 and the second encapsulation portion 520 are prepared in steps, where the first encapsulation portion 510 can well clad the second portion 320, which can improve the problem of degradation of the encapsulation performance of the encapsulation layer 500 due to holes easily formed between the encapsulation layer 500 and the spacer layer 300 when the thick encapsulation layer is made of the same material at a time.

Refer to FIG. 5, and FIG. 5 is a schematic flowchart of steps in a preparing method for a display panel provided in an embodiment of the present disclosure.

In some optional embodiments, the method further includes:

Prepare a pixel definition layer 200 on the substrate 100, where the pixel definition layer 200 includes pixel defining portions 210 and pixel openings 220 enclosed by the pixel defining portions 210, and at least part of each pixel electrode 800 is exposed from a respective pixel opening 220; the pixel openings 220 include first pixel openings 221, second pixel openings 222, and third pixel openings 223; the light-emitting units 410 include first light-emitting units 411 located within the first pixel openings 221, the second light-emitting units 412 located within the second pixel openings 222, and the third light-emitting units 413 located within the third pixel openings 223; the first encapsulation portion 510 includes a first encapsulation portion 501 located on a side, away from the substrate 100, of the first light-emitting unit 411, a second encapsulation portion 502 located on a side, away from the substrate 100, of the second light-emitting unit 412, and a third encapsulation portion 503 located on a side, away from the substrate 100, of the third light-emitting unit 413. Step S02 further includes:

Step S021: Dispose a first light-emitting material layer and a first encapsulation sub material layer on a side, away from the substrate 100, of the pixel definition layer 200, and pattern the first light-emitting material layer and the first encapsulation sub material layer to form a first light-emitting unit 411 and a first encapsulation portion 501.

Step S022: Continue to dispose a second light-emitting material layer and a second encapsulation sub material layer on the side, away from the substrate 100, of the pixel definition layer 200, and pattern the second light-emitting material layer and the second encapsulation sub material layer to form a second light-emitting unit 412 and a second encapsulation portion 502.

Step S023: Continue to dispose a third light-emitting material layer and a third encapsulation sub material layer on the side, away from the substrate 100, of the pixel definition layer 200, and pattern the third light-emitting material layer and the third encapsulation sub material layer to form a third light-emitting unit 413 and a third encapsulation portion 503.

Specifically, in the patterning process, the first encapsulation sub material layer located on the side wall of the first portion 310 is etched off to reduce the actual depth of the groove when the second encapsulation portion is deposited.

Step S024: a second encapsulation portion 520 on the first encapsulation portion 501, the second encapsulation portion 502, the third encapsulation portion 503, and the pixel definition layer 200 are prepared.

In these optional embodiments, since the first encapsulation portion 501, the second encapsulation portion 502, the third encapsulation portion 503, and the second encapsulation portion 520 are prepared respectively, the second encapsulation portion 520 is deposited on a side, away from the substrate 100, of the first encapsulation portion 501, the second encapsulation portion 502, and the third encapsulation portion 503, and the first encapsulation portion 510 and the second encapsulation portion 520 are prepared separately to avoid the problem of degradation of the encapsulation performance caused by holes formed in the excessively thick encapsulation layer 500.

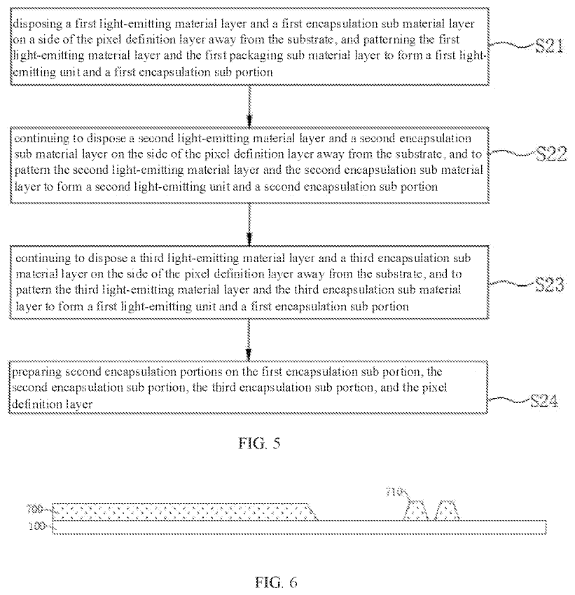

Taking the embodiment of FIG. 2 as an example, the preparing method provided in the embodiments of the present disclosure will be illustrated below with reference to FIGS. 6 to 15. The preparing method for the display panel 10 provided in the embodiments of the present disclosure includes:

Step 1, as shown in FIG. 6, a flattened material layer is disposed on a substrate 100, and the flattened material layer is patterned to form a flattened layer 700 and blocking portions 710.

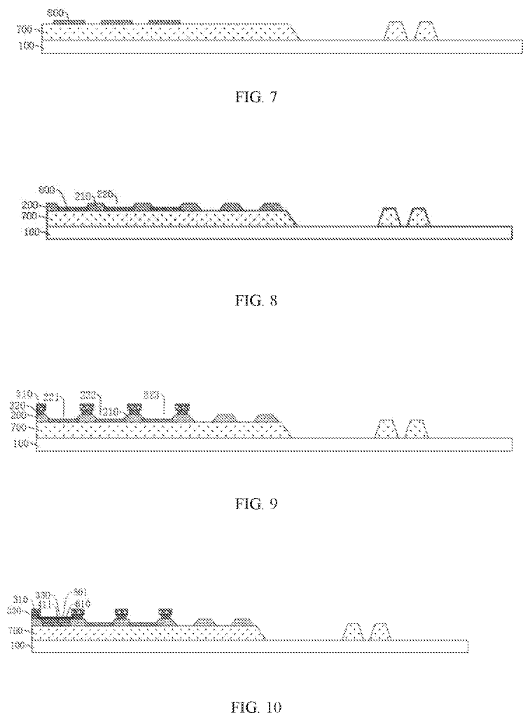

Step 2, as shown in FIG. 7, a pixel electrode 800 is prepared on the flattened layer 700.

Step 3, as shown in FIG. 8, a pixel definition material layer continues to be disposed on the substrate 100, and the pixel definition material layer is patterned to form a pixel definition layer 200 located in a display area AA.

Step 4, as shown in FIG. 9, a second sub material layer and a first sub material layer continue to be disposed on the substrate 100, and the second sub material layer and the first sub material layer are patterned to form a first portion 310 and a second portion 320 located on a pixel defining portion 210.

The first sub material layer and the second sub material layer may be patterned in two steps: in the first step, a photoresist is disposed on a side, away from the second sub material layer, of the first sub material layer, and the side, away from the second sub material layer, of the first sub material layer is etched using the photoresist to form the first portion 310; and in the second step, the second sub material layer continues to be etched laterally to form the second portion 320.

Step 5, as shown in FIG. 10, a first light-emitting material layer, a first electrode material layer, and a first encapsulation sub material layer continue to be disposed on the substrate 100, and the first light-emitting material layer, the first electrode material layer, and the first encapsulation sub material layer are patterned simultaneously to form a first light-emitting unit 411, a body portion 610, and a first encapsulation portion 501.

Specifically, the step that a first light-emitting material layer, a first electrode material layer, and a first encapsulation sub material layer continue to be disposed on the substrate 100, and the first light-emitting material layer, the first electrode material layer, and the first encapsulation sub material layer are patterned simultaneously to form a first light-emitting unit 411, a body portion 610, and a first encapsulation portion 501 includes:

A first light-emitting material, a first electrode material, and a first encapsulation sub material are sequentially disposed on the substrate 100, and the first light-emitting material layer, the first electrode material layer, and the first encapsulation sub material layer are formed in a first pixel opening, a second pixel opening, and a third pixel opening;

A photoresist is formed on a side, away from the substrate 100, of the first encapsulation sub material layer in the first pixel opening; and

The first light-emitting material layer, the first electrode material layer, and the first encapsulation sub material layer in the second pixel opening and the third pixel opening are etched to remove the second photoresist and form the first light-emitting unit 411, the body portion 610, and the first encapsulation portion 501.

Step 6, as shown in FIG. 11, a second light-emitting material layer, a second electrode material layer, and a second encapsulation sub material layer continue to be disposed on the substrate 100, and the second light-emitting material layer, the second electrode material layer, and the second encapsulation sub material layer are patterned simultaneously to form a second light-emitting unit 412, a body portion 610, and a second encapsulation portion 502.

Specifically, the step that a second light-emitting material layer, a second electrode material layer, and a second encapsulation sub material layer continue to be disposed on the substrate 100, and the second light-emitting material layer, the second electrode material layer, and the second encapsulation sub material layer are patterned simultaneously to form a second light-emitting unit 412, a body portion 610, and a second encapsulation portion 502 includes:

A second light-emitting material, a second electrode material, and a second encapsulation sub material are sequentially disposed on the substrate 100, and the second light-emitting material layer, the second electrode material layer, and the second encapsulation sub material layer are formed in the second pixel opening, the third pixel opening, and a side, away from the substrate 100, of the first encapsulation portion 201;

A photoresist is formed on a side, away from the substrate 100, of the second encapsulation sub material layer in the second pixel opening; and

The second light-emitting material layer, the second electrode material layer, and the second encapsulation sub material layer on the side, away from the substrate 100, of the first encapsulation portion, as well as the second light-emitting material layer, the second electrode material layer, and second encapsulation sub material layer in the third pixel opening are etched to remove the photoresist and form the second light-emitting unit 412, the body portion 610, and the second encapsulation portion 502.

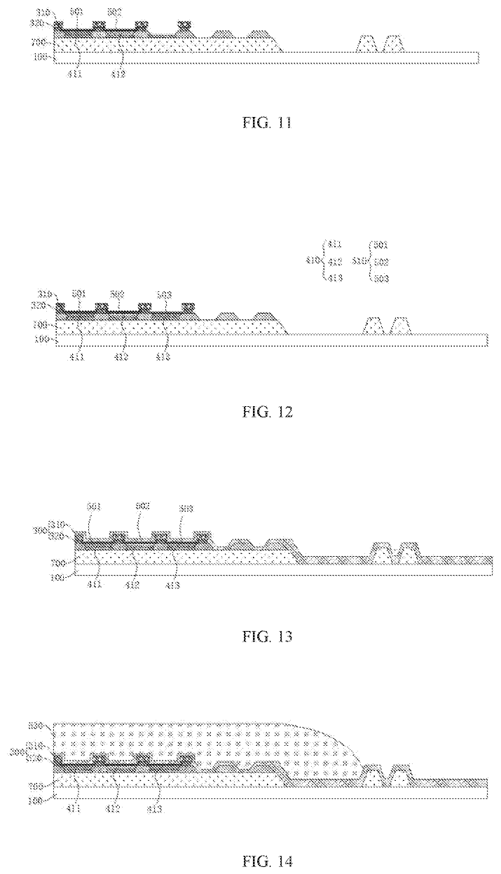

Step 7, as shown in FIG. 12, a third light-emitting material layer, a third electrode material layer, and a third encapsulation sub material layer are formed on the substrate 100, and the third light-emitting material layer, the third electrode material layer, and the third encapsulation sub material layer are patterned simultaneously to form a third light-emitting unit 413, a body portion 610, and a third encapsulation portion 503.

Specifically, the step that a third light-emitting material layer, a third electrode material layer, and a third encapsulation sub material layer are formed on the substrate 100, and the third light-emitting material layer, the third electrode material layer, and the third encapsulation sub material layer are patterned simultaneously to form a third light-emitting unit 413, a body portion 610, and a third encapsulation portion 503 includes:

A third light-emitting material, a third electrode material, and a third encapsulation sub material are sequentially disposed on the substrate 100, and the third light-emitting material layer, the third electrode material layer, and the third encapsulation sub material layer are formed on a side, away from the substrate 100, of the first encapsulation portion 501 and the second encapsulation portion 502 and in the third pixel opening;

A photoresist is formed on a side, away from the substrate 100, of the third encapsulation sub material layer in the third pixel opening; and

The third light-emitting material layer, the third electrode material layer, and the third encapsulation sub material layer on the side, away from the substrate 100, of the first encapsulation portion, as well as the third light-emitting material layer, the third electrode material layer, and third encapsulation sub material layer on the side, away from the substrate 100, of the second encapsulation portion are etched to remove the photoresist and form the third light-emitting unit 413, the body portion 610, and the third encapsulation portion 503.

Step 8, as shown in FIG. 13, a second encapsulation portion 520 is prepared on the first encapsulation portion 501, the second encapsulation portion 502, the third encapsulation portion 503, and the pixel definition layer 200. It should be noted that the second encapsulation portion 520 corresponding to the first encapsulation portion 501, the second encapsulation portion 502, and the third encapsulation portion 503 respectively may alternatively be formed in steps, that is, the second encapsulation portion above the first encapsulation portion 501 is formed after step 6 and before step 7, the second encapsulation portion 520 above the second encapsulation portion is formed after step 7 and before step 8, and the second encapsulation portion 520 corresponding to the third encapsulation portion is formed after step 8.

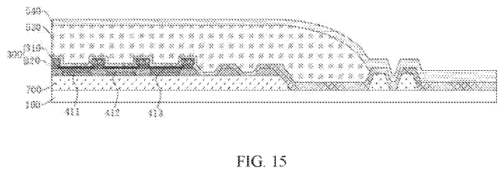

Step 9, as shown in FIG. 14, a third organic encapsulation portion 530 is disposed within an area enclosed by the blocking portion 710.

Step 10, as shown in FIG. 15, a fourth inorganic encapsulation portion 540 continues to be disposed on the substrate 100.

In the embodiments of the present disclosure, since the first encapsulation portion 501, the second encapsulation portion 502, the third encapsulation portion 503, and the second encapsulation portion 520 are prepared respectively, the second encapsulation portion 520 is deposited on a side, away from the substrate 100, of the first encapsulation portion 501, the second encapsulation portion 502, and the third encapsulation portion 503, and the first encapsulation portion 510 and the second encapsulation portion 520 are prepared separately to avoid the problem of degradation of the encapsulation performance caused by holes formed in the excessively thick encapsulation layer 500.

Those skilled in the art should understand that the above embodiments are all illustrative but not restrictive. Different technical features appearing in different embodiments can be combined to achieve beneficial effects. Those skilled in the art should be able to understand and implement other modified embodiments of the disclosed embodiments after studying the drawings, description, and claims. In the claims, the term “comprise” does not exclude other devices or steps; when an article is not modified by a quantifier, it is intended to include one or more articles, and may be exchanged with the “one or more articles” for use; and the terms “first” and “second” are used to denote names rather than to indicate any specific order. Any reference numerals in the claims should not be construed as limiting the scope of protection. The functions of a plurality of portions appearing in the claims can be implemented by a single hardware or software module. The appearance of certain technical features in different dependent claims does not mean that these technical features cannot be combined to achieve beneficial effects.

What is claimed is:

1. A display panel, comprising:
a substrate;
a spacer layer located on the substrate and comprising a first portion and a second portion located on a side of the first portion facing the substrate, an orthographic projection area of the first portion on the substrate being greater than that of the second portion on the substrate, the spacer layer enclosing an isolation space, and the spacer layer having a groove protruding to a side wall of the isolation space;
a light-emitting layer comprising a light-emitting unit located in the isolation space; and
an encapsulation layer located on a side of the light-emitting layer away from the substrate and comprising a first encapsulation portion and a second encapsulation portion that are stacked, at least a portion of the first encapsulation portion being located in the groove, and the second encapsulation portion being located on a side of the first encapsulation portion away from the substrate.

2. The display panel of claim 1, wherein the display panel further comprises:
a pixel definition layer located on the substrate, wherein the pixel definition layer comprises a plurality of pixel defining portions and a plurality of pixel openings enclosed by the pixel defining portions, and at least part of each pixel electrode is exposed from a respective pixel opening.

3. The display panel of claim 1, wherein a thickness of the first encapsulation portion is smaller than that of the second encapsulation portion.

4. The display panel of claim 1, wherein a material of the first encapsulation portion comprises silicon oxide or silicon oxynitride.

5. The display panel of claim 1, wherein a material of the second encapsulation portion comprises silicon nitride.

6. The display panel of claim 1, wherein a distance between a surface of the first portion facing the substrate and the substrate is defined as a first distance, a distance between a surface of the first encapsulation portion away from the substrate and the substrate is defined as a second distance, and the second distance is smaller than or equal to the first distance.

7. The display panel of claim 1, further comprising a first electrode layer located on a side of the light-emitting unit away from the substrate, wherein the first electrode layer comprises a body portion connected to the second portion.

8. The display panel of claim 7, wherein the first encapsulation portion is located on a side of the body portion away from the light-emitting unit, and the first encapsulation portion is located on the side of the first portion facing the substrate.

9. The display panel of claim 7, wherein the first encapsulation portion comprises:
a second covering portion covering a side surface of the second portion.

10. The display panel of claim 9, wherein the first encapsulation portion further comprises a first covering portion, the first covering portion covers a surface of the body portion away from the light-emitting unit, and the second covering portion is connected to a periphery of the first covering portion.

11. The display panel of claim 9, wherein the first encapsulation portion further comprises a third covering portion connected to a periphery of the second covering portion and covering the surface of the first portion facing the substrate.

12. The display panel of claim 7, wherein the display panel further comprises a filter unit, the filter unit is located between the body portion of the first electrode layer and the first encapsulation portion, a refractive index of the filter unit is defined as n0, a refractive index of the first encapsulation portion is defined as n1, and a refractive index of the second encapsulation portion is defined as n2, satisfying the following relationship:
$${n}_{1} = \sqrt{{n}_{0} *} {n}_{2} .$$

13. The display panel of claim 1, wherein the second encapsulation portion is at least partially located within the isolation space.

14. The display panel according to claim 1, wherein the second encapsulation portion comprises a first portion and a second portion that are integrated, the first portion is located within the isolation space, and the second portion is located on a surface of the spacer layer away from the substrate.

15. The display panel of claim 1, wherein the second encapsulation portion fully covers the first encapsulation portion.

16. The display panel of claim 1, wherein a thickness of the first encapsulation portion ranges from 0.1 μm to 0.5 μm.

17. The display panel of claim 1, further comprising a display area and a non-display area disposed around the display area, a blocking portion disposed in the non-display area and around the display area, wherein the encapsulation layer further comprises a third organic encapsulation portion, the third organic encapsulation portion is located on a side of the second encapsulation portion away from the substrate, and the third organic encapsulation portion is located within an area enclosed by the blocking portion.

18. A display device, comprising the display panel of claim 1.

19. A method for preparing a display panel, comprising:
preparing a spacer layer on a substrate, wherein the spacer layer comprises a first portion and a second portion located on a side of the first portion facing the substrate, an orthographic projection area of the first portion on the substrate is greater than that of the second portion on the substrate, the spacer layer encloses an isolation space, and the spacer layer has a groove protruding a side wall of the isolation space;
preparing a light-emitting layer and a encapsulation layer on the substrate, wherein the light-emitting layer comprises a light-emitting unit located in the isolation space, the encapsulation layer comprises a first encapsulation portion and a second encapsulation portion that are stacked, at least a portion of the first encapsulation portion is located in the groove, and the second encapsulation portion is located on a side of the first encapsulation portion away from the substrate.

20. The method of claim 19, wherein the method further comprises:
preparing a pixel definition layer on the substrate, wherein the pixel definition layer comprises pixel defining portions and pixel openings enclosed by the pixel defining portions, and at least part of each pixel electrode is exposed by a respective pixel opening: the pixel openings comprise first pixel openings, second pixel openings, and third pixel openings: the light-emitting unit comprises a first light-emitting unit located within respective first pixel opening, a second light-emitting unit located within respective second pixel opening, and a third light-emitting unit located within respective third pixel opening: the first encapsulation portion comprises a first encapsulation portion located on a side of the first light-emitting unit away from the substrate, a second encapsulation portion located on a side of the second light-emitting unit away from the substrate, and a third encapsulation portion located on a side of the third light-emitting unit away from the substrate; and
in the step of preparing a light-emitting layer and a encapsulation layer on the substrate, the method further comprises:
disposing a first light-emitting material layer and a first encapsulation sub material layer on a side of the pixel definition layer away from the substrate, and patterning the first light-emitting material layer and the first encapsulation sub material layer to form a first light-emitting unit and a first encapsulation portion;
continuing to dispose a second light-emitting material layer and a second encapsulation sub material layer on the side of the pixel definition layer away from the substrate, and to pattern the second light-emitting material layer and the second encapsulation sub material layer to form a second light-emitting unit and a second encapsulation portion;
continuing to dispose a third light-emitting material layer and a third encapsulation sub material layer on the side of the pixel definition layer away from the substrate, and to pattern the third light-emitting material layer and the third encapsulation sub material layer to form a third light-emitting unit and a third encapsulation portion; and
preparing second encapsulation portions on the first encapsulation portion, the second encapsulation portion, the third encapsulation portion, and the pixel definition layer.
